(19) United States
(12) Patent Application Publication
(10) Pub. No.: US 2017/0016971 A1
(43) Pub. Date: Jan. 19, 2017

(54) Segmented MRT

(71) Applicant: Björn Heismann, Erlangen (DE)

(72) Inventor: Björn Heismann, Erlangen (DE)

(21) Appl. No.: 14/800,505

(22) Filed: Jul. 15, 2015

(30) Foreign Application Priority Data
Jul. 15, 2015 (DE) 102014213722.5

(51) Int. Cl. G01R 33/561; G01R 33/385; G01R 33/36; G01R 33/30

(52) U.S. Cl. CPC G01R 33/5616; G01R 33/307; G01R 33/385; G01R 33/3614

(57) ABSTRACT

A method and a magnetic resonance tomography system are provided. The magnetic resonance tomography system is activated for transmitting a gradient field by an amplifier and a control with a gradient signal for creating the gradient field. The magnetic resonance tomography system includes a number of transmit segments activated for simultaneous transmission of radio-frequency pulses in each case of one or of a number of different frequencies by an amplifier and a control to excite a region in an examination object in each case.

This application claims the benefit of DE 10 2014 213 722.5, filed on Jul. 15, 2014, which is hereby incorporated by reference in its entirety.

### BACKGROUND

The present embodiments relate to methods and devices for MRT imaging.

EPI multi-slice imaging for magnetic resonance devices (e.g., MRTs or MRs), especially for examination of patients using magnetic resonance tomography, is known, for example, from David A. Feinberg, Kawin Setsompop “Ultra-fast MRI of the human brain with simultaneous multi-slice imaging,” Journal of Magnetic Resonance, 229, 2013, pp. 90-100.

### SUMMARY

The scope of the present invention is defined solely by the appended claims and is not affected to any degree by the statements within this summary.

The present embodiments may obviate one or more of the drawbacks or limitations in the related art. For example, MRT imaging is optimized.

### BRIEF DESCRIPTION OF THE DRAWINGS

FIG. 1 shows a simplified schematic diagram of a longitudinal section of the system structure of a segmented MR, of a z gradient field, and a transmitted RF field at a point in time, according to an embodiment;

FIG. 2 shows a simplified schematic diagram of a longitudinal section of the system structure of a segmented MR, of a z gradient field, and a transmitted RF field at a further point in time, according to an embodiment;

FIG. 3 shows a simplified schematic diagram of a cross-section of one embodiment of the system structure of a segmented MR; and

FIG. 4 shows a schematic of one embodiment of an MRT system.

### DETAILED DESCRIPTION

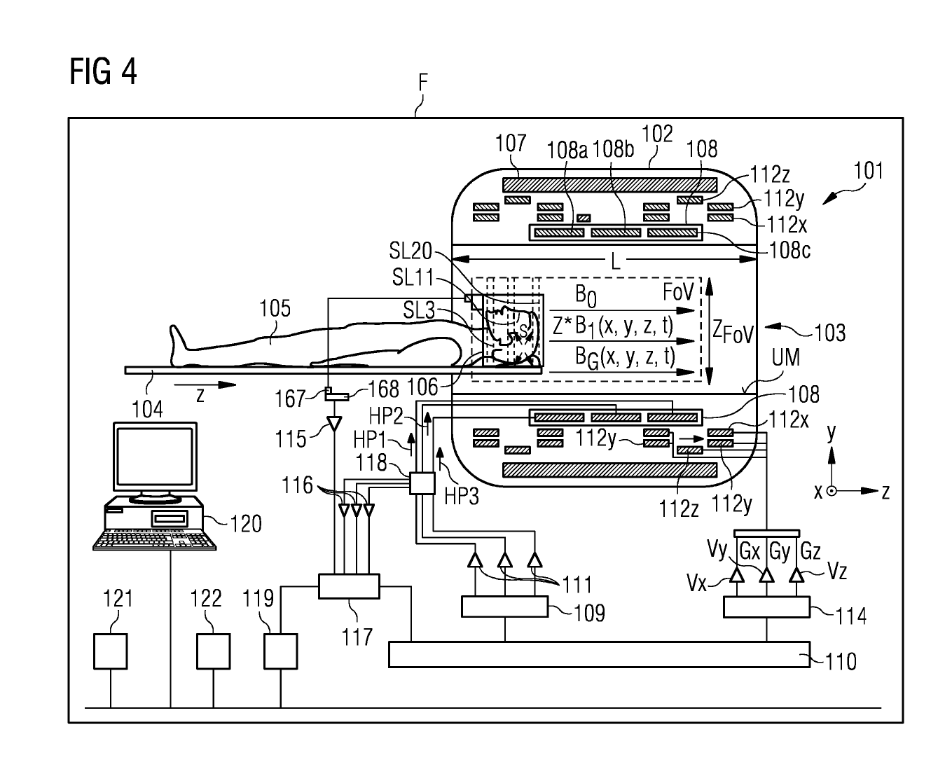

FIG. 4 shows one embodiment of an imaging magnetic resonance device MRT 101 (e.g., contained in a shielded room or Faraday cage F) including a hollow cylinder 102 having, for example, a tubular bore 103 into which a patient couch 104 bearing a body 105 (e.g., of an examination object such as a patient; with or without local coil arrangement 106) may be introduced in the direction of the arrow z so that images of the patient 105 may be generated by an imaging method. Disposed on the patient is, for example, a local coil arrangement 106 that may be used in a local region (e.g., a field of view (FoV)) of the MRT 101 to generate images of a subregion of the body 105 in the FoV. Signals of the local coil arrangement 106 may be evaluated (e.g., converted into images, stored or displayed) by an evaluation device (e.g., including elements 168, 115, 117, 119, 120, 121, etc.) of the MRT 101 that may be connected to the local coil arrangement 106 (e.g., via coaxial cable, wirelessly (element 167), etc.).

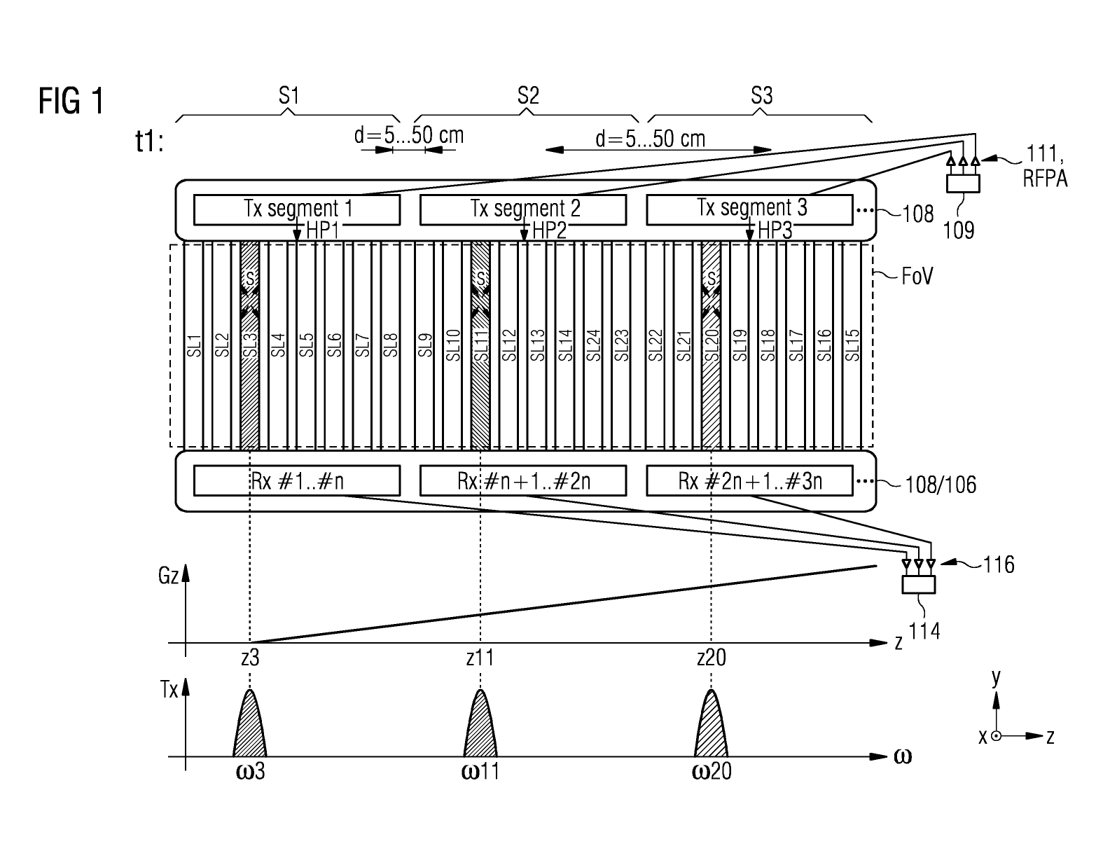

When a magnetic resonance device MRT 101 is used in order to examine a body 105 (e.g., an examination object or a patient) by magnetic resonance imaging, different magnetic fields that are coordinated with one another with precision in terms of temporal and spatial characteristics are radiated onto the body 105. A strong magnet (e.g., a cryomagnet 107) in a measurement chamber having a, for example, tunnel-shaped bore 103 generates a strong static main magnetic field B_{O} ranging, for example, from 0.2 Tesla to 3 Tesla or more. A body 105 that is to be examined, supported on a patient couch 104, is moved into a region of the main magnetic field B0 that is approximately homogeneous in the area of observation FoV. The nuclear spins of atomic nuclei of the body 105 are excited via magnetic radio-frequency excitation pulses B1(x, y, z, t) that are emitted via a radio-frequency antenna (and/or a local coil arrangement if necessary) depicted in greatly simplified form as a body coil 108 (e.g., multipart body coil 108a, 108b, 108c; accordingly S1, S2, S3 in FIG. 1). Radio-frequency excitation pulses (e.g., HF or RF) are generated, for example, by a pulse generation unit 109 that is controlled by a pulse sequence control unit 110. Following amplification by a radio-frequency amplifier 111, the pulses are directed to the radio-frequency antenna 108. The radio-frequency system shown in FIG. 4 is indicated only schematically. In other embodiments, more than one pulse generation unit 109, more than one radio-frequency amplifier 111, and a plurality of radio-frequency antennas 108 a, b, c are also used in a magnetic resonance device 101.

The magnetic resonance device 101 also includes gradient coils 112x, 112y, 112z by which magnetic gradient fields B_{G}(x, y, z, t) are radiated in the course of a measurement in order to provoke selective layer excitation and for spatial encoding of the measurement signal. The gradient coils 112x, 112y, 112z are controlled by a gradient coil control unit 114 (and, if appropriate, by way of amplifiers Vx, Vy, Vz) that, like the pulse generation unit 109, is connected to the pulse sequence control unit 110.

Signals emitted by the excited nuclear spins (e.g., of the atomic nuclei in the examination object) are received by the body coil 108a, b, c and/or at least one local coil arrangement 106, amplified by assigned radio-frequency preamplifiers 116, and further processed and digitized by a receive unit 117. The recorded measurement data is digitized and stored in the form of complex numeric values in a k-space matrix. A multidimensional Fourier transform may be used to reconstruct an associated MR image from the value-populated k-space matrix.

For a coil that may be operated in both transmit and receive mode (e.g., the body coil 108 or a local coil 106), correct signal forwarding is regulated by an upstream transceiver switch 118.

From the measurement data, an image processing unit 119 generates an image that is displayed to a user via an operator console 120 and/or stored in a memory unit 121. A central computer unit 122 controls the individual system components.

In MR tomography, images having a high signal-to-noise ratio (SNR) may be acquired by local coil arrangements (e.g., coils, local coils). These are antenna systems that are mounted in immediate proximity to (e.g., anterior), under (posterior), on, or in the body 105. In the course of an MR measurement, the excited nuclei induce a voltage in the individual antennas of the local coil. The induced voltage is amplified by a low-noise preamplifier (e.g., LNA, preamp) and forwarded to the receive electronics. High-field systems (e.g., 1.5 T-12 T or more) are used to improve the signal-to-noise ratio, even with high-resolution images. If more individual antennas may be connected to an MR receive system than there are receivers present, a switching matrix (e.g., also partly referred to or realized as RCCS), for example, is incorporated between receive antennas and receivers. The array routes the currently active receive channels (e.g., the array routes currently lying in the field of view of the magnet) to the receivers present. This enables more coil elements to be connected than there are receivers available, since in the case of whole-body coverage, only the coils that are located in the FoV or in the homogeneity volume of the magnet may be read out.

The term local coil arrangement 106 may describe, for example, an antenna system that may include, for example, one antenna element or a plurality of antenna elements (e.g., coil elements) configured as an array coil. These individual antenna elements are embodied, for example, as loop antennas (e.g., loops), butterfly coils, flex coils or saddle coils. A local coil arrangement includes, for example, coil elements, a preamplifier, further electronics (e.g., sheath current filters, etc.), a housing, supports, and may include a cable with plug-type connector by which the local coil arrangement is connected to the MRT system. A receiver 168 mounted on the MRT system side filters and digitizes a signal received, for example, wirelessly by a local coil 106 and passes the data to a digital signal processing device that may derive an image or a spectrum from the data acquired by a measurement. The digital signal processing device may and make the image or spectrum available to the user, for example, for subsequent diagnosis by the user and/or for storage in a memory.

FIGS. 1-3 show basic schematic diagrams of details of the system structure of exemplary embodiments of the segmented MRT 101.

One advantage of an embodiment may be a combination of a segmented Tx and Rx MRT architecture (e.g., with transmit antennas Tx* and/or transmit antenna controls and, possibly arranged radially with the antennas, receive antennas Rx#1 . . . Rx#3n and/or receive signal processing devices 117). This may apply with the potentials of a multiband MR (e.g., known per se from David A. Feinberg, Kawin Setsompop “Ultra-fast MRI of the human brain with simultaneous multi-slice imaging,” Journal of Magnetic Resonance 229 (2013) 90ff.) in body or head imaging, for example.

In accordance with FIG. 1, an MR system 101 with a segmented transmit and receive structure 108 (e.g., for the transmission of radio-frequency pulses B1(x, y, z, t) and for the receiving of signals Si from the patient 105 to be examined) is provided. In this system configuration, the simultaneous multi-slice imaging (e.g., “multiband MRI”) in, for example, Feinberg, Kawin Setsompop “Ultra-fast MRI of the human brain with simultaneous multi-slice imaging,” Journal of Magnetic Resonance 229, 2013, pp. 90-100 is realized advantageously.

In the version shown in FIG. 1, n segments (e.g., n=3; with the reference numbers S1, S2, S3), each with independent transmit capabilities (e.g., with transmit devices; with coils 108a-c and/or amplifiers 111 and/or control 109; transmit devices of the segments are labeled for the sake of simplicity with the reference characters “Tx segment 1”, “Tx segment 2”, “Tx segment 3”) and receive capability (e.g., receive devices or receivers; with coils 108a-c and/or amplifiers 116 and/or evaluation device 117; receive devices indicated for the sake of simplicity with the reference characters “Rx #1” to “Rx #n” in the first segment S1, “Rx #n+1” to “Rx #2n” in the second segment S2, “Rx #2n+1” to “Rx #3n” in the third segment S3), are realized in MRT 101. The n segments use the common basic field B0 and gradient field B_{G}(x, y, z, t) (in FIG. 1: the gradient field G_{z} in the z-direction of the MRT 101 is shown as an example) of the MRT 101.

For example, in FIG. 1, at a point in time t1, a transmit segment “Tx segment 1” (e.g., activated by a control 109 and amplifier 111 with radio-frequency pulses HP1 with a frequency Omega (w3)) with transmitted RF pulses during a gradient signal (e.g., including GZ in the z-direction) excites a region SL3 (e.g., at right angles to the z-direction) in the patient 105 at a position z3 in the FoV, while simultaneously a transmit segment “Tx segment 2” (e.g., also activated by a control 109 and amplifier 111 with radio-frequency pulses HP1 with a further frequency Omega w11) with transmitted RF pulses during a gradient signal excites a region SL11 (e.g., at right angles to the z-direction) in the patient 105 at a position z3 in the FoV, and simultaneously a transmit segment “Tx segment 3” (e.g., also activated by a control 109 and amplifier 111 with radio-frequency pulses HP with a frequency Omega (w20)) with transmitted RF pulses TX during a gradient signal excites a region SL20 (e.g., at right angles to the z-direction) in the patient 105 at a position z3 in the FoV.

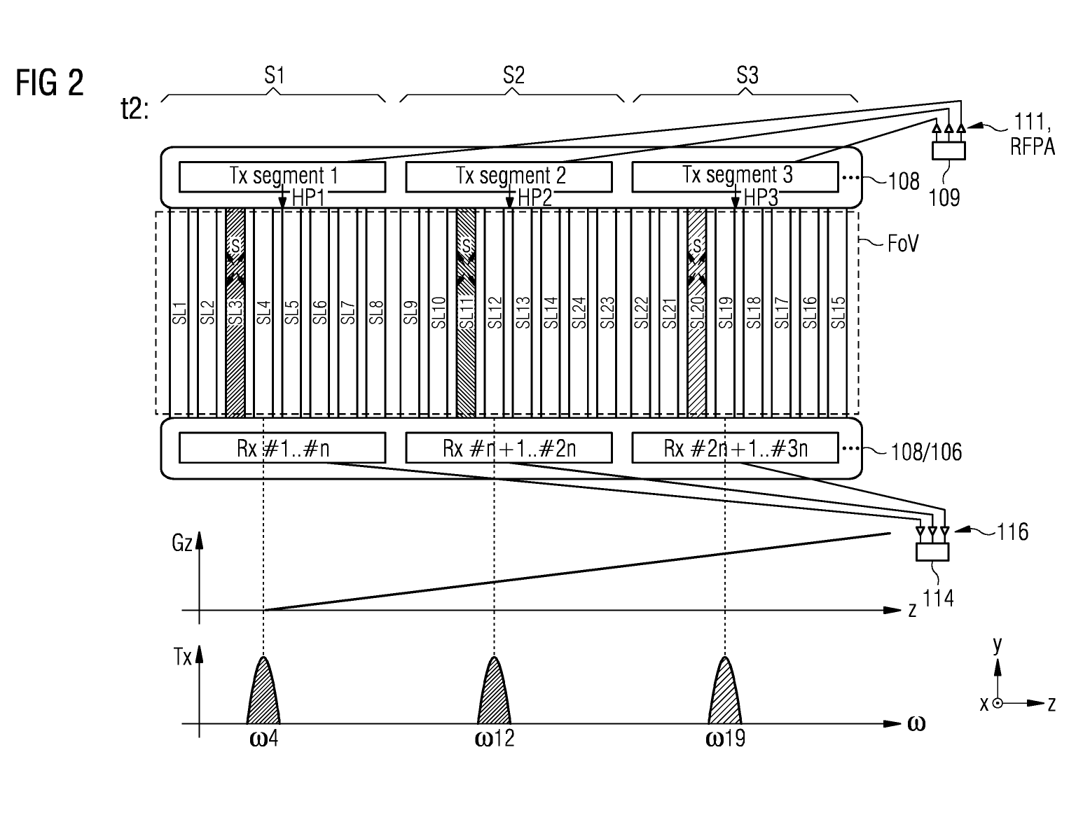

In accordance with FIG. 2, for example, chronologically afterwards at a further point in time t2 activated by each of the three transmit segments “Tx segment 1”, “Tx segment 2”, “Tx segment 3” (e.g., with antennas activated by a control 109 and amplifier 111) with at least one radio-frequency signal pulse in each case (e.g., by three simultaneous pulses of the frequencies w4, w12, w19) during a region-selecting gradient signal (e.g., GZ as ramp in the z-direction), a further region SL4, SL12, SL19 (e.g., at right angles to the z-direction) may be activated in each case (e.g., a region SL4 may be excited by an RF pulse (HP, B1(x, y, z, t) with a frequency Omega(w4)) during the gradient signal GZ (e.g., in the z-direction for example) by transmit segment “Tx segment 1”, for example. Simultaneously, a region SL12 may be excited by an RF pulse (HP, B1(x, y, z, t) with a frequency Omega(w12)) during the gradient signal GZ (e.g., in the z-direction) by transmit segment “Tx segment 2”, for example, and simultaneously, a region SL19 (e.g., through the patient 105; at right angles to the z-direction) in the FoV may be excited by a transmit segment “Tx segment 3” (e.g., by an RF pulse (HP, B1(x, y, z, t) with a frequency Omega (w19)) during the gradient signal GZ in the z-direction). The pulses with one frequency each have a bandwidth indicated in FIG. 1, FIG. 2 around the respective frequency (e.g., wider than a peak).

An advantage of multiband excitation in this geometry may include each segment S1, S2, S3 of a respective region (e.g., S3, S11, S20 or at another point in time S4, S12, S19), in a patient 105 to be examined (e.g., excited by an RF pulse having three/more frequency components) being exited simultaneously (e.g., with RF pulses) and being measurable at the same time by one, a number of, or all receive channels (e.g., “Rx #1”-“Rx #n”; “Rx #n+1”-“Rx #2n”; “Rx #2n+1”-“Rx #3n”) of the transmitting segment S1, S2, S3 in the respective region (e.g., S3, S11, S20 or at a different point in time S4, S12, S19).

Antennas of the transmit segments shown simplified in FIG. 1 (e.g., “Tx segment 1”, “Tx segment 2”, “Tx segment 3”) and antennas of the receive devices of the MRT 101 shown simplified in FIG. 1 (e.g., “Rx #1”-“Rx #n”, “Rx #n+1”-“Rx #2n”, “Rx #2n+1”-“Rx #3n”) may, for example, just be antennas for transmitting or just antennas for receiving in each case (e.g., which then in 108 a, b, c may lie radially above one another in each case), or may be antennas used for transmitting and also for receiving in each case.

Regions (e.g., S3, S11, S20 or at another point in time S4, S12, S19), that are excited simultaneously during a gradient signal in each case by one or more RF pulses (B1(x, y, z, t)) of a number of frequencies w4, w12, w19 exciting one of the number of regions, may be at a spatial distance d from one another as in the example shown (e.g., may be non-contiguous) or may adjoin one another.

The shown spatial distance d (e.g., d=5-50 cm) of the number of regions (e.g., three; S3, S11, S20 or at another point in time S4, S12, S19) excited (e.g., by simultaneous RF pulses having a number of/three frequency components) from one another may in such cases have an effect on the receipt (e.g., on the g-factor; of a GRAPPA or SENSE reconstruction).

In a first approximation, by n segments S1, S2, S3 (in FIG. 1, n=3), with a sufficiently large distance of d=5 to 50 cm, a speed factor n may be obtained in volume recordings.

With a zFOV (e.g., diameter of the FOV in the z-direction) of 50 cm and MRT tunnel diameters of 60 to 70 cm, it appears from theoretical considerations that, for example, approximately two, three, or four segments that may equate to corresponding acceleration of the imaging are advantageous.

In such cases, it may be advantageous if a simultaneous recording of the slice signals, as in an MRT 3D sequence, is involved. Thus, the signal-to-noise ratio of the images obtained, unlike with other acceleration methods, may not have to be reduced by the acceleration factor.

For head imaging (e.g., recording an image of the head of the patient 105 in MRT 101), with the z-FOV, the FOV may also be reduced in the lateral direction x, so that a similar number of segments and resulting acceleration would be able to be assumed. It may be advantageous if not only the EPI as the main field of application of the multiband MR is accelerated, but also standard protocols with TSEs and GREs may be accelerated.

An advantageous configuration of the system in this case may be provided so that the segment subdivision in the center of the magnet is denser than at the outside (e.g., four segments; S1, S2, S3, fourth segment not shown) in the interior with, for example, d=5 cm and two further segments in the exterior with, for example, d=15 cm.

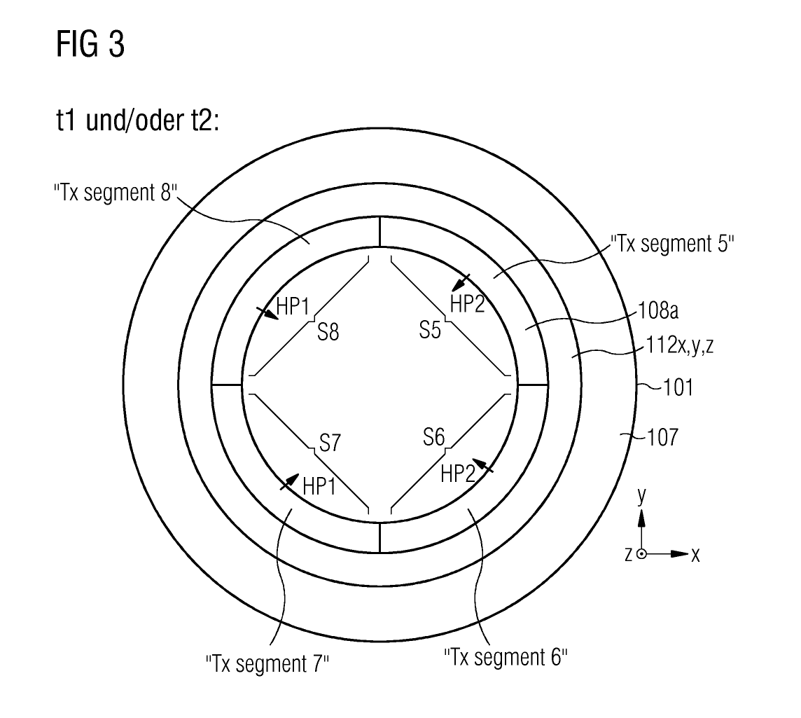

As FIG. 3 shows, in a simplified diagram, it is, in addition to or instead of a segmentation as in FIG. 1, 2, also advantageously possible to segment a transmit antenna 108 (e.g., an RF transmit antenna) in the MRT 101 not only in the z-direction but instead of or in addition to also in the cylinder plane (e.g., in cross-section or circumferential) of the MRT 101, and to be activated for transmission (e.g., simultaneous transmission) of RF pulses (e.g., the same as or different than RF pulses of the segments S1, S2, S3 in the z-direction).

Four cylinder surface segments S5, S6, S7, S8 with an angular coverage in each case of 90° may be formed and activated for transmission (e.g., simultaneous transmission) of RF pulses (e.g., the same as or different than the pulses of segments S1, S2, S3).

Through this, in each case, a subarea of one of the excited regions SL1-SL24 (shown in FIG. 1, FIG. 2) may be more strongly excited than another subarea (e.g., in regions S1-S8 of a segment S1 more strongly than in regions SL15-22 of another segment S3, and/or in at least one segment S1 in FIG. 1, 2 at the top (y) more strongly or more weakly than at the bottom and/or in at least one segment S3 in a horizontal direction (x) more strongly than in the opposing direction etc.). Thus, a 2*2*2 to 2*2*4 configuration of the segments is then produced in, for example, lateral (x) and coronal/vertical (y) and axial (z-) direction. The acceleration of the imaging may thus also be created in the sagittal (x) and coronal (y) patient direction.

The segment transmission channels (e.g., transmit devices in the form of the transmit segments “Tx segment 1”, “Tx segment 2”, “Tx segment 3”), in an embodiment (e.g., similar to an at least internally-known activation of receive channels with a switchover device “Rx-Switchbox” for switching over a number of receive channels to fewer amplifiers), may also be kept switchable (e.g., as activation for switchover of segment transmit channels “Tx segment 1”, “Tx segment 2”, “Tx segment 3” to fewer amplifiers 111 than segment transmit channels), so that, in an application example, a maximum number of two or three amplifiers (e.g., RFPA, 111) may be used. This may significantly cut potential expenditure for the additional segment transmit channels (e.g., “Tx segment 1”, “Tx segment 2”, “Tx segment 3”).

This method is able to be combined with all known speed advantages on the sequence side (e.g., multiecho excitation, compressed sensing, image filters, iterative reconstruction, radial undersampling, etc.).

Possible further advantages and embodiments may be as follows.

The speed of the imaging may be increased. In one embodiment, the speed advantages of the “multiband” MRT 101 may be linked to the logic of the explicit use of the transmit power.

In one embodiment, the transmit power may be concentrated on one segment (e.g., S1) in order to achieve an improved SNR there with a correspondingly higher B1 magnetic field or to achieve an increased measurement speed.

Through a segmentation of a transmit antenna 108 of an MRT 101, the SAR in the individual transmit areas (e.g., in the patient) is also able to be explicitly controlled. In a number of applications, the lower SAR in one segment may be used for increasing the B1 and thus SNR or scan speed.

The increase in the number of RF amplifiers (e.g., transmit amplifiers or RFPAs) 111 may be compensated for entirely or partly by the reduction of the power of the transmit amplifiers 111 in part on the cost side (e.g., with the use of a distribution device (Tx-Switchbox), which limits the number of RFPAs to between two and four).

Different combinations of Rx and Tx channels may be provided.

Embodiments may be used for optimizing body imaging (e.g., Body MR”; with FOVs of 50 cm).

A possibly existing (in parts unused) high number of Rx channels (number of receive channels) of high-end MR systems may be converted into a clinically advantageous acceleration.

The elements and features recited in the appended claims may be combined in different ways to produce new claims that likewise fall within the scope of the present invention. Thus, whereas the dependent claims appended below depend from only a single independent or dependent claim, it is to be understood that these dependent claims may, alternatively, be made to depend in the alternative from any preceding or following claim, whether independent or dependent. Such new combinations are to be understood as forming a part of the present specification.

While the present invention has been described above by reference to various embodiments, it should be understood that many changes and modifications can be made to the described embodiments. It is therefore intended that the foregoing description be regarded as illustrative rather than limiting, and that it be understood that all equivalents and/or combinations of embodiments are intended to be included in this description.

1. A magnetic resonance tomography system comprising:
a plurality of transmit segments that are activatable for simultaneous transmission of a radio frequency pulse of a different frequency in each case with a control, such that in each case a region is excited with a radio frequency pulse in an examination object.

2. The magnetic resonance tomography system of claim 1, wherein one transmit segment of the plurality of transmit segments is configured, at a point in time, to transmit radio frequency pulses of different first frequencies simultaneously, such that a number of regions are simultaneously excited in the examination object, and
wherein the plurality of transmit segments are configured, at a further point in time, to transmit radio-frequency pulses at second frequencies simultaneously, such that a number of further regions are excited simultaneously in the examination object, the second frequencies being different than the first frequencies and different from one another.

3. The magnetic resonance tomography system of claim 1, wherein through the simultaneous pulses of different frequencies, a number of regions of the examination object are simultaneously excitable into transmitting signals, and
wherein the magnetic resonance tomography system further comprises receivers configured to receive the transmitting signals.

4. The magnetic resonance tomography system of claim 1, wherein transmit segments of the plurality of transmit segments comprise coils that are connected to amplifiers that are activatable via at least one activation device.

5. The magnetic resonance tomography system of claim 3, wherein the receivers comprise coils that are connected to amplifiers that are connected to at least one evaluation device.

6. The magnetic resonance tomography system of claim 3, wherein transmit segments of the plurality of transmit segments, the receivers, or the transmit segments and the receivers comprise coils spatially distanced from one another.

7. The magnetic resonance tomography system of claim 1, wherein regions that are simultaneously excited by RF pulses of a number of frequencies have a spatial distance from one another.

8. The magnetic resonance tomography system of claim 7, wherein the spatial distance is between 5 cm and 50 cm, inclusive.

9. The magnetic resonance tomography system of claim 3, wherein signals transmitted in each case from a region excited by at least one radio-frequency pulse of a transmit segment of the plurality of transmit segments are evaluatable in each case by the receivers of a segment including the transmit segment

10. The magnetic resonance tomography system of claim 9, wherein the signals are evaluatable in each case by all the receivers of only the segment.

11. The magnetic resonance tomography system of claim 3, wherein a portion of transmit segments or all transmit segments of the plurality of transmit segments, the receivers, or a combination thereof are disposed behind one another in an axial direction of a bore of the magnetic resonance tomography system.

12. The magnetic resonance tomography system of claim 3, wherein a subset of transmit segments or all transmit segments of the plurality of transmit segments, the receivers, or a combination thereof are disposed next to one another in a circumferential direction of a bore of the magnetic resonance tomography system.

13. The magnetic resonance tomography system of claim 12, wherein the subset of transmit segments or all transmit segments of the plurality of transmit segments, the receivers, or a combination thereof are disposed next to one another in a circumferential direction of the bore within four cylinder surface segments with an angular coverage of 90° of the circumference of the bore in each case.

14. The magnetic resonance tomography system of claim 1, further comprising transmit segments that are activatable for transmission of an RF field by an amplifier and a control with RF signals in each case, in order to transmit a field simultaneously having pulses of a number of frequencies, and at a further point in time to transmit a field with pulses of a number of further frequencies different from the frequencies of the field.

15. The magnetic resonance tomography system of claim 3, wherein antennas of the plurality of transmit segments and antennas of the receivers are only transmitting antennas, only receiving antennas, or antennas for both receiving and transmitting.

16. The magnetic resonance tomography system of claim 3, wherein the plurality of transmit segments comprises only two, three, or four transmit segments, the receivers comprise only two, three, or four receivers, or a combination thereof.

17. The magnetic resonance tomography system of claim 1, wherein transmit segments of the plurality of transmit segments that are nearer to a center of a Field of View are at a short distance from one another, have a smaller width than transmit segments of the plurality of transmit segments that are further away from the center of the Field of View, or a combination thereof.

18. The magnetic resonance tomography system of claim 17, wherein four transmit interior segments of the plurality of transmit segments have a spatial distance of 5 cm near to the center, and two further segments of the plurality of transmit segments further away from the center have a spatial distance of 15 cm.

19. The magnetic resonance tomography system of claim 1, further comprising a switchover device configured to switch over a number of transmit segments of the plurality of transmit segments to fewer amplifiers than transmit segments.

20. The magnetic resonance tomography system of claim 1, wherein the magnetic resonance tomography system is configured to concentrate RF transmit power of the magnetic resonance tomography system or of body coils of the magnetic resonance tomography system at one point in time to one transmit segment of the plurality of transmit segments.

21. The magnetic resonance tomography system of claim 3, wherein the plurality of transmit segments, the receivers, or the plurality of transmit segments and the receivers are configured to carry out an echo-planar (EPI) imaging or protocols with turbo spin echo (TSE) and gradient echo (GRE).

22. The magnetic resonance tomography system of claim 1, wherein transmit coils of the plurality of transmit segments are disposed in a bore, in a local coil, or in the bore and in the local coil of the magnetic resonance tomography system.

23. The magnetic resonance tomography system of claim 1, further comprising one or more receivers,
wherein receive coils of the one or more receivers are disposed in a bore, in a local coil, or in the bore and the local coil of the magnetic resonance tomography system.

24. The magnetic resonance tomography system of claim 1, wherein the magnetic resonance tomography system is activatable to transmit a gradient field by an amplifier and a control with a gradient signal for creating a gradient field.

25. The magnetic resonance tomography system of claim 1, wherein the region is a slice.

26. A method for operating a magnetic resonance tomography system, the method comprising:
simultaneously exciting a number of regions in an examination object, the exciting of the number of regions comprising transmitting, by a plurality of transmit segments of the magnetic resonance tomography system, at a point in time, radio-frequency pulses of different frequencies simultaneously; and
simultaneously exciting a number of further regions in the examination object, the further regions being different than the regions, the exciting of the number of further regions comprising simultaneously transmitting, by the plurality of transmit segments, at a further point in time, radio-frequency pulses of further frequencies different than the frequencies and different from one another.
